(19) United States
(12) Patent Application Publication
(10) Pub. No.: US 2026/0342344 A1
(43) Pub. Date: Oct. 29, 2026

(54) CLOCK AND DATA RECOVERY DEVICE AND METHOD FOR CLOCK AND DATA RECOVERY

(71) Applicant: HIMAX TECHNOLOGIES LIMITED, Tainan City (TW)

(72) Inventor: YuShyang Huang, Tainan City (TW)

(73) Assignee: HIMAX TECHNOLOGIES LIMITED, Tainan City (TW)

(21) Appl. No.: 19/187,969

(22) Filed: Apr. 23, 2025

(51) Int. Cl. H03L 7/099; H03L 7/107; H03L 7/195

(52) U.S. Cl. CPC H03L 7/0998; H03L 7/1072; H03L 7/195

(57) ABSTRACT

A clock and data recovery device and a method for clock and data recovery are provided. The clock and data recovery device includes a digital loop filter. The digital loop filter generates a control signal according to a phase detection signal. The digital loop filter comprises a proportional gain circuit, a biased voting circuit, an integral gain circuit, an initial clock setting circuit, and a signal processing circuit. The biased voting circuit generates a biased voting value according to the phase detection signal and a preset range. The integral gain circuit generates an integral gain signal according to the biased voting value. The initial clock setting circuit provides an initial clock signal to an output node of the initial clock setting circuit in a start time period, and provides the integral gain signal to the output node of the initial clock setting circuit after the start time period.

### BACKGROUND

### Technical Field

The present invention generally relates to a clock and data recovery technology in an electronic device, and more particularly to a clock and data recover device and a digital loop filter.

### Description of Related Art

The clock and data recovery technology is often applied in data transmission interfaces of the electronic device, with the goal of obtaining a clock signal from the data stream of the data transmission interface and frequently calibrating the clock signal, so as to accurately utilize the clock signal for extracting data from the data stream. The clock and data recovery device can be categorized into an analog form and a digital form. The clock and data recovery device of the digital form may encounter issues where the clock signal generated by the clock and data recovery device maintains at an incorrect frequency due to a large clock frequency offset of the clock signal. And, a phase detector of the clock and data recovery device may only output the phase polarity (e.g., the lead or the lag of two clock signals), and it may not output the amplitude of the difference of the two clock signals, so as to narrow the frequency acquisition range. One of the problems to be solved is how to prevent the clock and data recovery device of the digital form from maintaining the clock data at an incorrect frequency.

The disclosure provides a clock and data recovery device and a method for clock and data recovery, which prevents the clock and data recovery device from maintaining a clock data at an incorrect frequency, and makes the frequency acquisition range wider.

A clock and data recovery device according to the disclosure is provided. The clock and data recovery device includes a phase detector, a digital loop filter, and a phase interpolator. The phase detector receives an input signal and a first signal, wherein the phase detector compares a phase difference of the input signal and the first signal to generate a phase detection signal. The digital loop filter generates a control signal according to the phase detection signal. The phase interpolator is coupled to the digital loop filter and the phase detector. The phase interpolator generates the first signal according to reference clock signals and the control signal. The digital loop filter comprises a proportional gain circuit, a biased voting circuit, an integral gain circuit, an initial clock setting circuit, and a signal processing circuit. The proportional gain circuit receives the phase detection signal and generates a first gain signal. The biased voting circuit is coupled to the proportional gain circuit. The biased voting circuit generates a biased voting value according to the phase detection signal and a preset range with a first value and a second value, wherein the biased voting value is one of zero, a positive unit value, and a negative unit value. The integral gain circuit is coupled to the biased voting circuit. The integral gain circuit generates an integral gain signal according to the biased voting value. The initial clock setting circuit is coupled to the integral gain circuit. The initial clock setting circuit provides an initial clock signal to an output node of the initial clock setting circuit in a start time period, and provides the integral gain signal to the output node of the initial clock setting circuit after the start time period. The signal processing circuit is coupled to the proportional gain circuit and the output node of the initial clock setting circuit. The signal processing circuit generates the control signal according to the first gain signal and a signal in the output node of the initial clock setting circuit.

A method for clock and data recovery according to the disclosure is provided. The A method for clock and data recovery comprises following steps: receiving an input signal and a first signal; comparing a phase difference of the input signal and the first signal to generate a phase detection signal; generating a control signal according to the phase detection signal; and, generating the first signal according to reference clock signals and the control signal. A step for generating the control signal according to the phase detection signal comprises: receiving the phase detection signal to generate a first gain signal; generating a biased voting value according to the phase detection signal and a preset range with a first value and a second value, wherein the biased voting value is one of zero, a positive unit value, and a negative unit value; generating an integral gain signal according to the biased voting value; providing an initial clock signal to an input node of a signal processing circuit in a start time period, and providing the integral gain signal to the input node of the signal processing circuit after the start time period; and, generating the control signal according to the first gain signal and a signal on the input node of the signal processing circuit by the signal processing circuit.

Based on the above, the clock and data recovery device described in the embodiment of the disclosure adjusts the initial clock signal in a start time period as a clock signal with a negative clock frequency offset, and drifts a clock frequency offset of the clock upward from a negative value to a stable value gradually according to the biased voting value of the biased voting circuit. The biased voting value of the biased voting circuit filters out the phase error between the input signal and the first signal differently due to the transformation formula from the phase detection signal to the biased voting value. Thus, the clock and data recovery device and a method for clock and data recovery may prevent the clock and data recovery device from maintaining a clock data at an incorrect frequency, and makes the frequency acquisition range of the phase detector wider.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of a clock and data recovery device according to an embodiment of the disclosure.

FIG. 2 is a schematic view of a digital loop filter of FIG. 1 according to an embodiment of the disclosure.

FIG. 3 is a schematic view of a transformation formula of a biased voting circuit of FIG. 2 according to an embodiment of the disclosure.

FIG. 4 is a schematic view of the adjustment of a clock skew in the control signal by the clock skew compensation circuit of FIG. 2 according to an embodiment of the disclosure.

FIG. 5 is a schematic view of clock frequency offset between the input signal and the first signal according to an embodiment of the disclosure.

FIG. 6 is a flow chart of a method for clock and data recovery according to an embodiment of the disclosure.

FIG. 7 is a flow chart of the step S630 of FIG. 6 according to an embodiment of the disclosure.

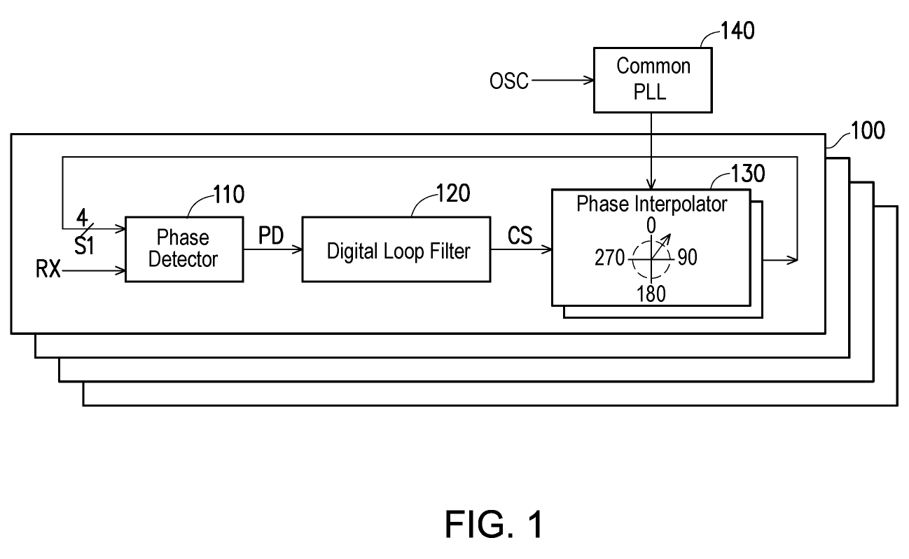

FIG. 1 is a schematic view of a clock and data recovery device 100 according to an embodiment of the disclosure. The clock and data recovery device 100 is applicable to data transmission in electronic devices. For example, the clock and data recovery device 100 may determine the clock signal from an input signal (such as an input signal RX) and use this clock signal to extract the required data from the data stream of the input signal. Assuming there are four input signals RX coming into the system of the clock and data recovery device 100, the architecture of the clock and data recovery device 100 would be replicated four times for processing these four input signals RX.

Referring to FIG. 1, the clock and data recovery device 100 includes a phase detector 110, a digital loop filter 120, and a phase interpolator 130. The clock and data recovery device 100 further includes a common phase-locked loop (PLL) circuit 140. The phase detector 110 receives an input signal RX and a first signal S1. The phase detector 110 compares a phase difference of the input signal RX and the first signal S1 to generate a phase detection signal PD. The digital loop filter 120 generates a control signal CS according to the phase detection signal PD.

The phase interpolator 130 is coupled to the digital loop filter 120 and the phase detector 110. The phase interpolator 130 generates the first signal S1 according to the reference clock signals generated by the common PLL circuit 140 and the control signal CS. The common PLL circuit 140 generates multiple reference clock signals with different phases (e.g., reference clock signals each have phases of 0°, 90°, 180°, and 270°) according to an oscillating signal OSC which is generated by an oscillator.

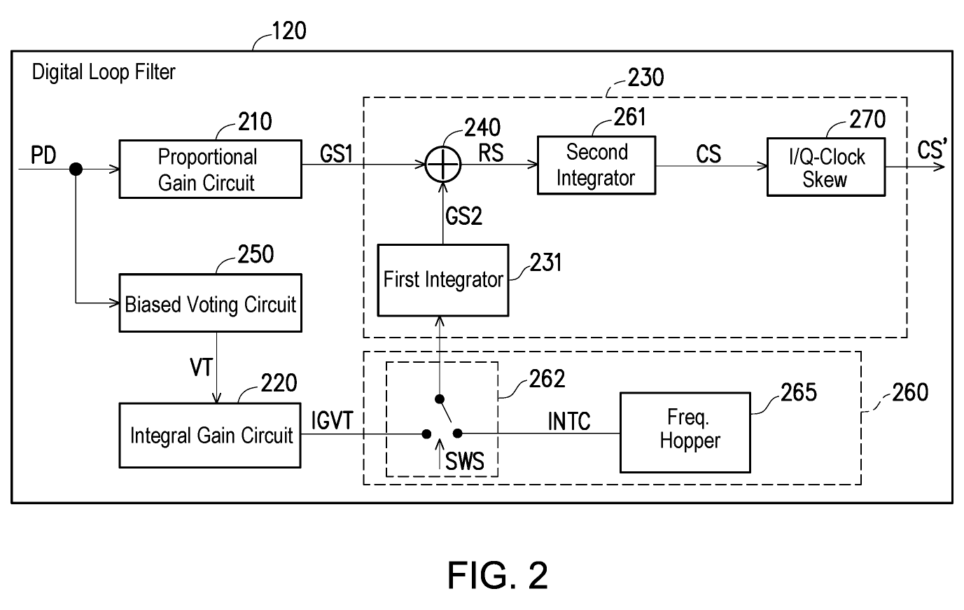

FIG. 2 is a schematic view of the digital loop filter 120 of FIG. 1 according to an embodiment of the disclosure. Referring to FIG. 2, the digital loop filter 120 includes a proportional gain circuit 210, a biased voting circuit 250, an integral gain circuit 220, an initial clock setting circuit 260, and a signal processing circuit 230. The proportional gain circuit 210 receives the phase detection signal PD and generates a first gain signal GS1 according to a proportional gain KP. The proportional gain KP is a gain in the proportional path of the digital loop filter 120.

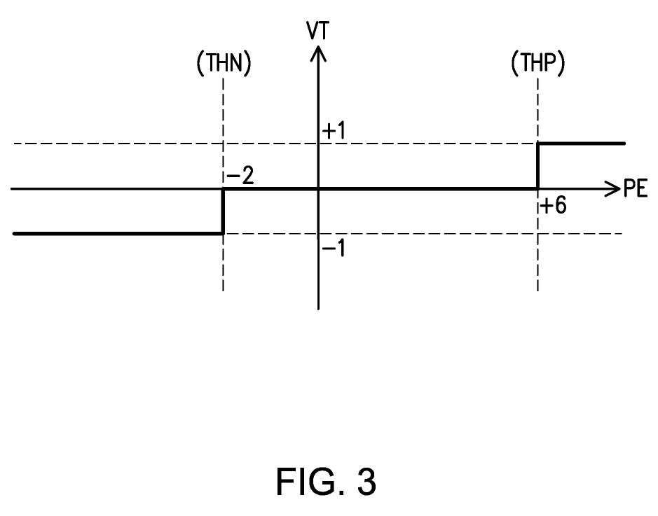

The biased voting circuit 250 is coupled to the proportional gain circuit 210 for receiving the phase detection signal PD. The biased voting circuit 250 generates a biased voting value VT according to the phase detection signal PD, a preset range with a first value (e.g., a first value THP) and a second value (e.g., a second value THN), and a transformation formula presented in FIG. 3. The biased voting value VT is one of zero (e.g.,’0’), a positive unit value (e.g.,’+1’), and a negative unit value (e.g.,’-1’). The detail of the transformation formula of the biased voting circuit 250 is described in FIG. 3.

FIG. 3 is a schematic view of the transformation formula of the biased voting circuit 250 of FIG. 2 according to an embodiment of the disclosure. The X-axis of the transformation formula in FIG. 3 is a phase error PE of the phase detection signal PD, and the Y-axis of the transformation formula in FIG. 3 is the value of the biased voting value VT. The preset range is set in the first value THP (e.g., ‘+6’) and the second value THN (e.g., ‘-2’). In the embodiment, the first value THP (‘+6’) is larger than the second value THN (‘-2’). The second value THN is less than zero. An absolute value (‘6’) of the first value THP (‘+6’) is not the same as an absolute value (‘2’) of the second value THN (‘-2’). In the transformation formula of FIG. 3, while the phase error PE of the phase detection signal PD is larger than the first value THP (e.g., ‘+6’), it means that the phase of the input signal RX leads the phase of the first signal S1 by more than 6 units, thus the biased voting value VT is set as the positive unit value (‘+1’); while the phase detection signal PD is in the preset range with the first value THP (‘+6’) and the second value THN (‘-2’), it means that the phase of the input signal RX is approximately equal to the phase of the first signal S1, thus the biased voting value VT is set as zero (‘0’); and, while the phase detection signal PD is less than the second value THN (‘-2’), it means that the phase of the input signal RX lags behind the phase of the first signal S1 by more than 2 units, the biased voting value VT is the negative unit value (‘-1’). In other words, the biased voting circuit 250 does not action while the phase detection signal PD is in the preset range. The biased voting circuit 250 generates the biased voting value VT as ‘+1’ while the phase detection signal PD is larger than the first value THP (e.g., ‘+6’), and the biased voting circuit 250 generates the biased voting value VT as ‘-1’ while the phase detection signal PD is less than the second value THN (e.g., ‘-2’).

Referring back to FIG. 2, the integral gain circuit 220 is coupled to the biased voting circuit 250. The integral gain circuit 220 generates an integral gain signal IGVT according to the biased voting value VT and an integral gain KI. The integral gain KI is a gain in the integral path of the digital loop filter 120.

The initial clock setting circuit 260 is coupled to the integral gain circuit 220. The initial clock setting circuit 260 provides an initial clock signal INTC to an output node of the initial clock setting circuit 260 in a start time period. And, the initial clock setting circuit 260 provides the integral gain signal IGVT to the output node of the initial clock setting circuit 260 after the start time period. The initial clock signal INTC is a clock signal with a negative clock frequency offset. In detail, the initial clock setting circuit 260 includes a switch circuit 262 and a frequency hopper 265. The frequency hopper 265 provides the initial clock signal INTC to a second input node of the switch circuit 262. The first input node of the switch circuit 262 is coupled to the integral gain circuit 220 for receiving the integral gain signal IGVT. The second input node of the switch circuit 262 is coupled to the frequency hopper 265 for receiving the initial clock signal INTC. The switch circuit 262 provides one of the integral gain signal IGVT and the initial clock signal INTC to the output node of the switch circuit 262 according to a switching signal SWS. While the switching signal SWS is enabled in the start time period, the switch circuit 262 provides the initial clock signal INTC to the output node of the switch circuit 262. While the switching signal SWS is disabled after the start time period, the switch circuit 262 provides the integral gain signal IGVT to the output node of the switch circuit 262. The output node of the switch circuit 262 is the same as the output node of the initial clock setting circuit 260.

The signal processing circuit 230 is coupled to the proportional gain circuit 210 and the output node of the initial clock setting circuit 260. The signal processing circuit 230 generates the control signal CS according to the first gain signal GS1 and a signal in the output node of the initial clock setting circuit 260. In detail, the signal processing circuit 230 includes a first integrator 231, an adder 240, and a second integrator 261. The first integrator 231 is coupled to the output node of the initial clock setting circuit 260 for receiving the signal on the output node of the initial clock setting circuit 260. The first integrator 231 integrates the signal on the output node of the initial clock setting circuit 260 to generate a second gain signal GS2.

The adder 240 is coupled to the proportional gain circuit 210 and the first integrator 231. The adder 240 adds the first gain signal GS1 and the second gain signal GS2 to generate a result signal RS. The second integrator 261 is coupled to the adder 240. The second integrator 261 integrates the result signal RS on the output node of the adder 24 to generate the control signal CS.

The signal processing circuit 230 further includes a clock skew compensation circuit 270. The clock skew compensation circuit 270 is coupled to the second integrator 261. The clock skew compensation circuit 270 adjusts a clock skew in the control signal CS to generate an adjusted control signal CS’ on the output node of the digital loop filter 120.

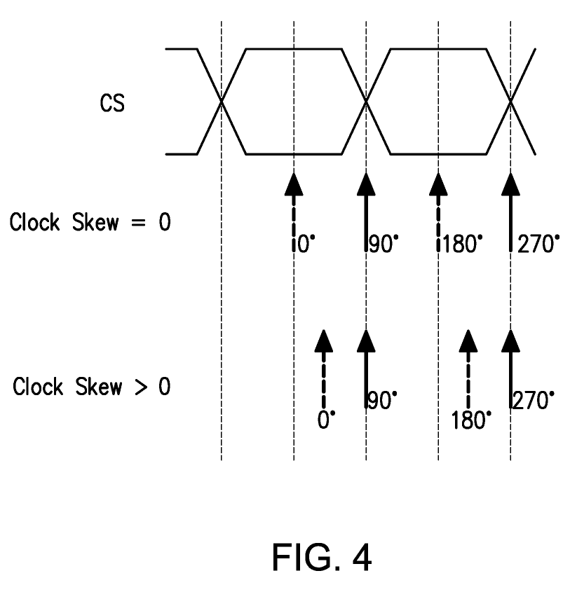

FIG. 4 is a schematic view of the adjustment of a clock skew in the control signal CS by the clock skew compensation circuit 270 of FIG. 2 according to an embodiment of the disclosure. Referring to FIG. 4, the control signal CS are adjusted while the clock skew is not zero ‘0’. In FIG. 4, while the clock skew is equal to ‘0’, the data extracting from the data stream by the clock signals with have phases of 0°, 90°, 180°, and 270° correctly. But, while the clock skew is bigger to ‘0’, the data extracting from the data stream by the clock signals with have phases of 0°, 90°, 180°, and 270° will cause phase shifts (or offsets). The clock skew compensation circuit 270 adjusts the clock skew in the control signal CS.

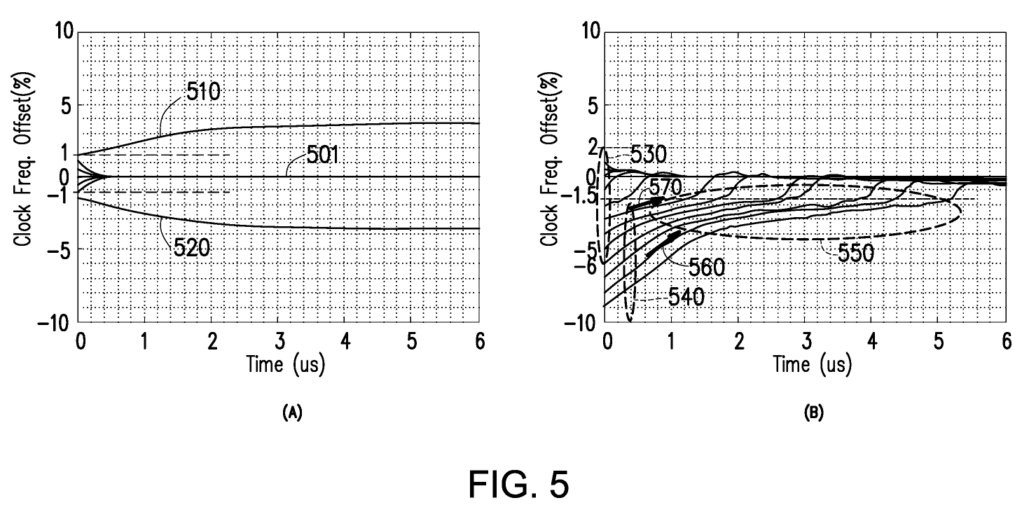

FIG. 5 is a schematic view of clock frequency offset between the input signal RX and the first signal S1 according to an embodiment of the disclosure. The part (A) of FIG. 5 presents the clock frequency offset with a clock and data recovery device, which does not have the biased voting circuit 250 and the initial clock setting circuit 260. The integral gain circuit 220 generates an integral gain signal according to the phase detection signal PD and the integral gain KI while the clock and data recovery device 100 does not have the biased voting circuit 250, and the first integrator 231 integrates the integral gain signal according to the phase detection signal PD to generate the second gain signal GS2 while the clock and data recovery device 100 does not have the initial clock setting circuit 260. While the difference between the input signal RX and the first signal S1 is larger than or less than a preset clock frequency offset (e.g., ‘+1 %’ or ‘-1 %’), the clock and data recovery device, which does not have the biased voting circuit 250 and the initial clock setting circuit 260, is maintained in the incorrect frequency shown as the line 510 or the line 520 of part (A) in FIG. 5. Only the clock frequency offset between the input signal RX and the first signal S1 is in the preset range of ‘+1 %’ and ‘-1 %’, the clock and data recovery device, which does not have the biased voting circuit 250 and the initial clock setting circuit 260, is maintained in the correct frequency shown as the line 501. Thus, the clock and data recovery device, which does not have the biased voting circuit 250 and the initial clock setting circuit 260, has a narrow frequency acquisition range.

The part (B) of FIG. 5 presents the clock frequency offset with a clock and data recovery device 100, which have the biased voting circuit 250 and the initial clock setting circuit 260. The initial clock setting circuit 260 makes the first signal S1 as a clock signal with a negative clock frequency offset (shown as the mark 530 to the mark 540 of part (B) in FIG. 5) in the start time period, and drifts the clock frequency offset of the clock upward from a negative value to a stable value gradually (shown as the mark 550 of part (B) in FIG. 5) according to the biased voting value VT of the biased voting circuit 250. The biased voting value VT of the biased voting circuit 250 filters out the phase error between the input signal RC and the first signal S1 differently due to the transformation formula in FIG. 3 from the phase detection signal PD to the biased voting value VT.

In FIG. 5, the values of the first value THP and the second value THN affect the adjustment speed of the clock signal. For example, the slope of the arrow 560 represents the adjustment speed of the clock signal based on the first value THP which is set to ‘+6’ and the second value THN which is set to ‘-2’, and the slope of the arrow 570 represents the adjustment speed of the clock signal based on the first value THP which is set to ‘+1’ and the second value THN which is set to ‘-1’. Since the slope of the arrow 560 is steeper than the slope of the arrow 570, the adjustment speed based on the first value THP ‘+6’ and the second value THN ‘-2’ is faster than the adjustment speed based on the first value THP ‘+1’ and the second value THN ‘-1’.

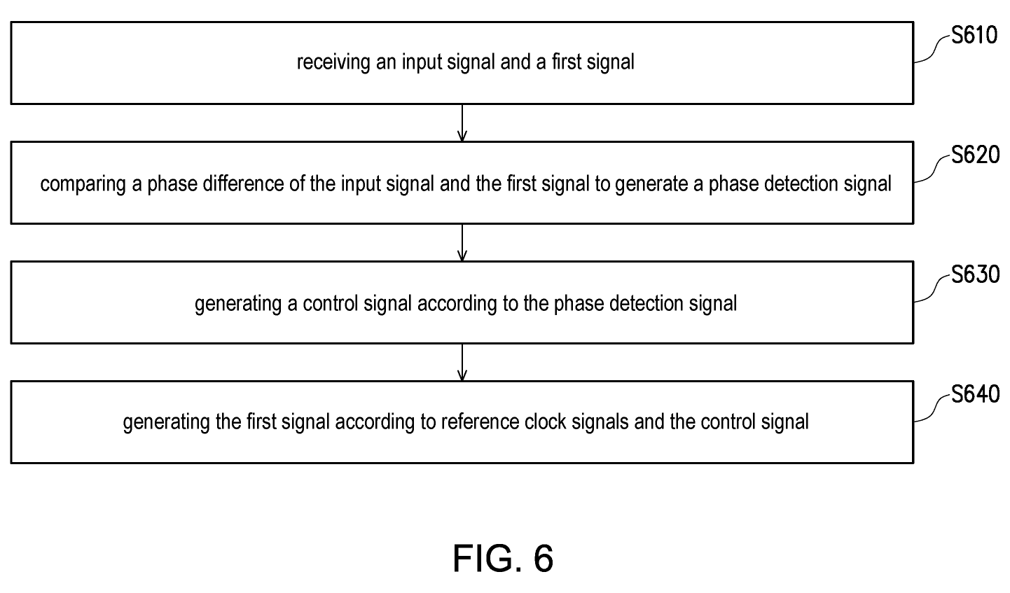

FIG. 6 is a flow chart of a method for clock and data recovery according to an embodiment of the disclosure. The method for clock and data recovery is applied to the clock and data recovery device 100 of FIG. 1. Referring to FIGS. 1 and 6, in the step S610, the phase detector 110 receives an input signal RX and a first signal S1. In the step S620, the phase detector 110 compares a phase difference of the input signal RX and the first signal S1 to generate a phase detection signal PD. In the step S630, the digital loop filter 120 generates a control signal CS according to the phase detection signal PD. In the step S640, the phase interpolator 130 generates the first signal S1 according to the reference clock signals generated by the common PLL circuit 140 and the control signal CS.

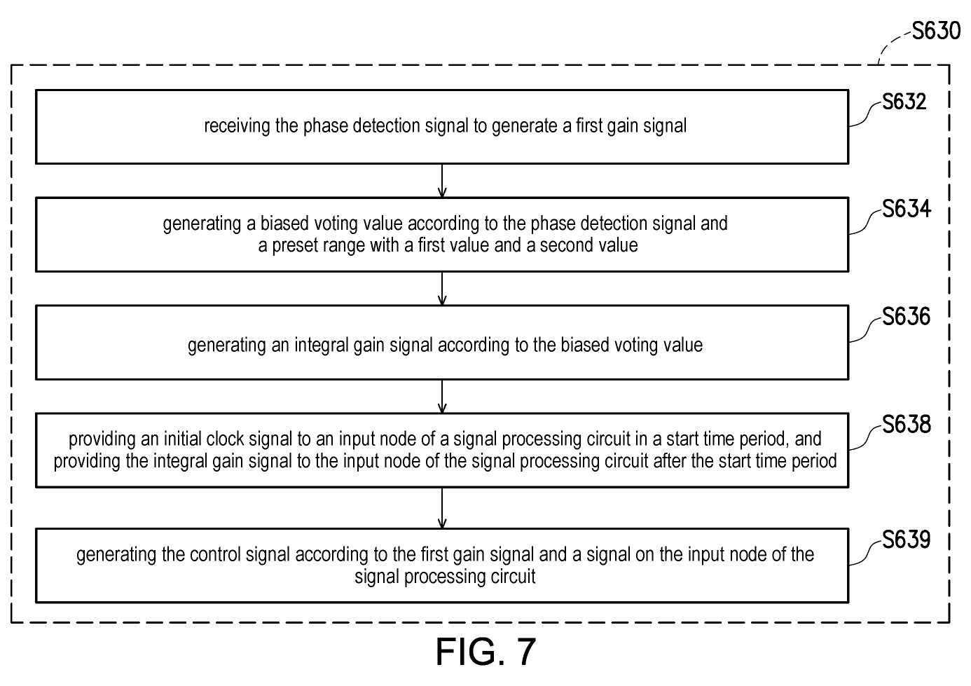

FIG. 7 is a flow chart of the step S630 of FIG. 6 according to an embodiment of the disclosure. Referring to FIGS. 2 and 7, the step S630 includes the steps S632 to S639. In the step S632, the proportional gain circuit 210 receives the phase detection signal PD and generates a first gain signal GS1 according to a proportional gain KP. In the step S634, the biased voting circuit 250 generates a biased voting value VT according to the phase detection signal PD, a preset range with a first value (e.g., a first value THP), wherein the biased voting value VT is one of zero (e.g.,’0’), a positive unit value (e.g.,’+1’), and a negative unit value (e.g.,’-1’).

In the step S636, the integral gain circuit 220 generates an integral gain signal IGVT according to the biased voting value VT and an integral gain KI.

In the step S638, the initial clock setting circuit 260 provides an initial clock signal INTC to an output node of the initial clock setting circuit 260 in a start time period, and, the initial clock setting circuit 260 provides the integral gain signal IGVT to the output node of the initial clock setting circuit 260 after the start time period.

In the step S639, the signal processing circuit 230 generates the control signal CS according to the first gain signal GS1 and a signal in the output node of the initial clock setting circuit 260. Please may refer to the above embodiments for details of the steps S610-S640 of FIG. 6 and the steps S632-S639 of FIG. 7.

In summary, the clock and data recovery device described in the embodiment of the disclosure adjusts the initial clock signal in a start time period as a clock signal with a negative clock frequency offset, and drifts a clock frequency offset of the clock upward from a negative value to a stable value gradually according to the biased voting value of the biased voting circuit. The biased voting value of the biased voting circuit filters out the phase error between the input signal and the first signal differently due to the transformation formula from the phase detection signal to the biased voting value. Thus, the clock and data recovery device and a method for clock and data recovery may prevent the clock and data recovery device from maintaining a clock data at an incorrect frequency, and makes the frequency acquisition range of the phase detector wider.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A clock and data recovery device, comprising:
a phase detector, receiving an input signal and a first signal, wherein the phase detector compares a phase difference of the input signal and the first signal to generate a phase detection signal;
a digital loop filter, generating a control signal according to the phase detection signal; and
a phase interpolator, coupled to the digital loop filter and the phase detector, wherein the phase interpolator generates the first signal according to reference clock signals and the control signal,
wherein the digital loop filter comprises:
a proportional gain circuit, receiving the phase detection signal and generating a first gain signal;
a biased voting circuit, coupled to the proportional gain circuit, wherein the biased voting circuit generates a biased voting value according to the phase detection signal and a preset range with a first value and a second value, wherein the biased voting value is one of zero, a positive unit value, and a negative unit value;
an integral gain circuit, coupled to the biased voting circuit, wherein the integral gain circuit generates an integral gain signal according to the biased voting value;
an initial clock setting circuit, coupled to the integral gain circuit, wherein the initial clock setting circuit provides an initial clock signal to an output node of the initial clock setting circuit in a start time period, and provides the integral gain signal to the output node of the initial clock setting circuit after the start time period; and
a signal processing circuit, coupled to the proportional gain circuit and the output node of the initial clock setting circuit, wherein the signal processing circuit generates the control signal according to the first gain signal and a signal in the output node of the initial clock setting circuit.

2. The clock and data recovery device of claim 1, wherein the first value is larger than the second value, the second value is less than zero, an absolute value of the first value is not the same as an absolute value of the second value,
the biased voting value is zero while the phase detection signal is in the preset range with the first value and the second value,
the biased voting value is the positive unit value while the phase detection signal is larger than the first value, and,
the biased voting value is the negative unit value while the phase detection signal is less than the second value.

3. The clock and data recovery device of claim 1, wherein the initial clock signal is a clock signal with a negative clock frequency offset.

4. The clock and data recovery device of claim 1, wherein the initial clock setting circuit comprising:
a frequency hopper, provides the initial clock signal;
a switch circuit, a first input node of the switch circuit is coupled to the integral gain circuit, a second input node of the switch circuit is coupled to the frequency hopper,
the switch circuit provides one of the integral gain signal and the initial clock signal to an output node of the switch circuit according to a switching signal,
wherein the switching signal is enabled in the start time period, and the switch circuit provides the initial clock signal to the output node of the switch circuit,
wherein the switching signal is disabled after the start time period, and the switch circuit provides the integral gain signal to the output node of the switch circuit.

5. The clock and data recovery device of claim 1, wherein the signal processing circuit comprising:
a first integrator, coupled to the output node of the initial clock setting circuit, wherein the first integrator integrates a signal on the output node of the initial clock setting circuit to generate a second gain signal;
an adder, coupled to the proportional gain circuit and the first integrator, wherein the adder adds the first gain signal and the second gain signal to generate a result signal; and
a second integrator, coupled to the adder, wherein the second integrator integrates the result signal on an output node of the adder to generate the control signal.

6. The clock and data recovery device of claim 5, wherein the signal processing circuit further comprising:
a clock skew compensation circuit, coupled to the second integrator,
wherein the clock skew compensation circuit adjusts a clock skew in the control signal.

7. A method for clock and data recovery, comprising:
receiving an input signal and a first signal;
comparing a phase difference of the input signal and the first signal to generate a phase detection signal;
generating a control signal according to the phase detection signal; and
generating the first signal according to reference clock signals and the control signal,
wherein a step for generating the control signal according to the phase detection signal comprises:
receiving the phase detection signal to generate a first gain signal;
generating a biased voting value according to the phase detection signal and a preset range with a first value and a second value, wherein the biased voting value is one of zero, a positive unit value, and a negative unit value;
generating an integral gain signal according to the biased voting value;
providing an initial clock signal to an input node of a signal processing circuit in a start time period, and providing the integral gain signal to the input node of the signal processing circuit after the start time period; and
generating the control signal according to the first gain signal and a signal on the input node of the signal processing circuit by the signal processing circuit.

8. The method for clock and data recovery of claim 7, wherein the first value is larger than the second value, the second value is less than zero, an absolute value of the first value is not the same as an absolute value of the second value,
the biased voting value is zero while the phase detection signal is in the preset range with the first value and the second value,
the biased voting value is the positive unit value while the phase detection signal is larger than the first value, and,
the biased voting value is the negative unit value while the phase detection signal is less than the second value.

9. The method for clock and data recovery of claim 7, wherein the initial clock signal is a clock signal with a negative clock frequency offset.

10. The method for clock and data recovery of claim 7, a step for generating the control signal according to the first gain signal and the signal on the input node of the signal processing circuit comprising:
integrating the signal on the input node of the signal processing circuit to generate a second gain signal;
adding the first gain signal and the second gain signal to generate a result signal; and
integrating the result signal to generate the control signal.

11. The method for clock and data recovery of claim 10, the step for generating the control signal according to the first gain signal and the signal on the input node of the signal processing circuit further comprising:
adjusting a clock skew in the control signal by a clock skew compensation circuit.
